(19) United States
(12) Patent Application Publication
(10) Pub. No.: US 2025/0385650 A1
(43) Pub. Date: Dec. 18, 2025

(54) LOW-FREQUENCY STABILIZER FOR INDUCTOR-LESS LOW-NOISE AMPLIFIER

(71) Applicant: QUALCOMM Incorporated, San Diego, CA (US)

(72) Inventors: Prakash THOPPAY EGAMBARAM, San Diego, CA (US); Aleksandar Miodrag TASIC, San Diego, CA (US); Marco VIGILANTE, San Diego, CA (US)

(21) Appl. No.: 18/746,399

(22) Filed: Jun. 18, 2024

(51) Int. Cl. H03F 3/24; H03F 1/08

(52) U.S. Cl. CPC H03F 3/245; H03F 1/086; H03F 2200/294; H03F 2200/451

(57) ABSTRACT

A system for wireless communications includes a low-noise amplifier (LNA) and an impedance circuit coupled to an output of the LNA. The impedance circuit includes a transistor, wherein a drain of the transistor is coupled to the output of the LNA, and a source of the transistor is coupled to a ground or a reference potential. The impedance circuit also includes a resistor-capacitor (RC) filter coupled to the output of the LNA and a gate of the transistor.

### FIELD

Aspects of the present disclosure relate generally to wireless communications, and, more particularly, to low-noise amplifiers.

### BACKGROUND

A wireless device (e.g., smart phone) may transmit and receive radio frequency (RF) signals in one or more wireless networks (e.g., a long-term evolution (LTE) network, a fifth generation (5G) network, a wireless local area network (WLAN), etc.). To receive RF signals, the wireless device includes one or more antennas and one or more low-noise amplifiers (LNAs) configured to amplify RF signals received by the one or more antennas.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a system for wireless communications. The system includes a low-noise amplifier (LNA) and an impedance circuit coupled to an output of the LNA. The impedance circuit includes a transistor, wherein a drain of the transistor is coupled to the output of the LNA, and a source of the transistor is coupled to a ground or a reference potential. The impedance circuit also includes a resistor-capacitor (RC) filter coupled to the output of the LNA and a gate of the transistor.

A second aspect relates to a system for wireless communications. The system includes a low-noise amplifier (LNA), and an impedance circuit coupled to an output of the LNA. The impedance circuit includes a first transistor, wherein a drain of the first transistor is coupled to the output of the LNA, and a second transistor, wherein a drain of the second transistor is coupled to a source of the first transistor, and a source of the second transistor is coupled to a ground or a reference potential. The impedance circuit also includes a resistor-capacitor (RC) filter coupled to the output of the LNA, a gate of the first transistor, and a gate of the second transistor.

### BRIEF DESCRIPTION OF THE DRAWINGS

FIG. 1A shows an example of a system including a low-noise amplifier (LNA) and a receive circuit according to certain aspects of the present disclosure.

FIG. 1B shows an example of the system of FIG. 1A in which the LNA and the receive circuit are integrated on a chip according to certain aspects of the present disclosure.

FIG. 2 shows an exemplary implementation of the receive circuit of FIGS. 1A and 1B according to aspects of the present disclosure according to certain aspects of the present disclosure.

FIG. 3 shows an example of an inductor-less LNA according to certain aspects of the present disclosure.

FIG. 4 shows an example of an impedance circuit coupled to the LNA of FIG. 3 according to certain aspects of the present disclosure.

FIG. 5 is a plot showing an example of an impedance of the impedance circuit versus frequency according to certain aspects of the present disclosure.

FIG. 6 shows another example of an impedance circuit coupled to the LNA of FIG. 3 according to certain aspects of the present disclosure.

FIG. 7 shows an example of an impedance circuit coupled between an LNA and a receive circuit according to certain aspects of the present disclosure.

FIG. 8 shows another example of an impedance circuit coupled between an LNA and a receive circuit according to certain aspects of the present disclosure.

FIG. 9 shows an example of an impedance circuit including a p-type metal-oxide-semiconductor (PMOS) transistor according to certain aspects of the present disclosure.

FIG. 10 shows an example of an impedance circuit including a first PMOS transistor and a second PMOS transistor according to certain aspects of the present disclosure.

FIG. 11 is a diagram of an environment including an electronic device that includes a transceiver according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A wireless device may include one or more low-noise amplifiers (LNAs) configured to amplify radio frequency (RF) signals received by one or more antennas. The wireless device may be implemented as any suitable wireless device, such as a cellular or mobile phone, a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, and so forth.

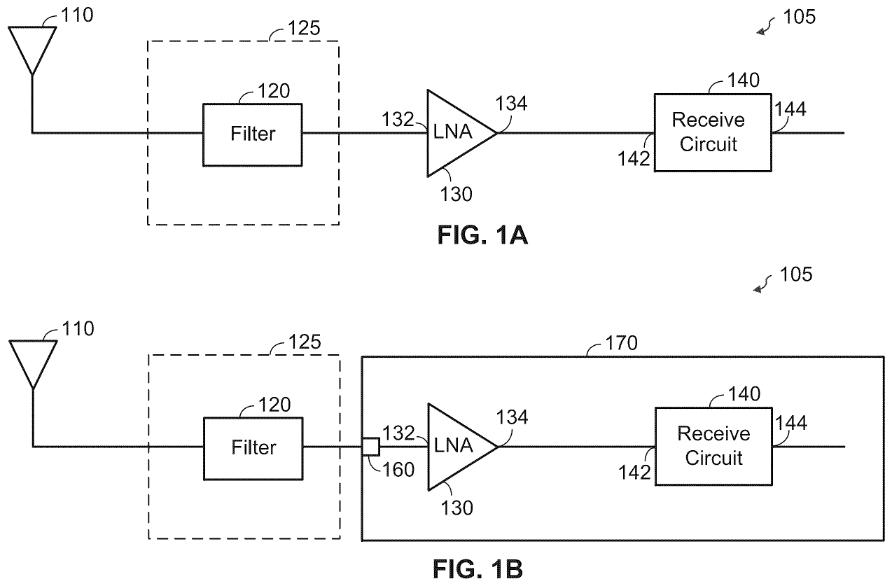

FIG. 1A shows an example of a system 105 including an LNA 130 according to certain aspects. The system 105 may be included in the wireless device for receiving wireless signals (e.g., radio frequency (RF) signals in the GHz frequency range). In the example shown in FIG. 1A, the system 105 also includes an antenna 110, a front-end circuit 125 (also referred to an RF front-end (RFFE) circuit), and a receive circuit 140. The receive circuit 140 may be included in a transceiver. Although one antenna 110, one front-end circuit 125, and one LNA 130 are shown in FIG. 1A, it is to be appreciated that the wireless device may include multiple antennas (e.g., arranged in an array), multiple front-end circuits, and/or multiple LNAs.

In the example in FIG. 1A, the LNA 130 has an input 132 and an output 134, in which the front-end circuit 125 is coupled between the antenna 110 and the input 132 of the LNA 130. The receive circuit 140 has an input 142 and an output 144. The input 142 of the receive circuit 140 is coupled to the output 134 of the LNA 130. The output 144 of the receive circuit 140 may be coupled to a baseband processor (also referred to as a modem), an intermediate frequency (IF) circuit, or another type of circuit.

In one example, the front-end circuit 125 may be configured to condition an RF signal from the antenna 110 before the RF signal is input to the LNA 130. For example, the front-end circuit 125 may include a filter 120 and/or one or more other circuits. In certain aspects, the filter 120 may be a bandpass filter configured to pass an RF signal received from the antenna 110 within a desired frequency band (i.e., pass band) to the LNA 130 while filtering out signals (e.g., interfering signals) outside the desired frequency band. The front-end circuit 125 may include one or more other circuits (not shown in FIG. 1A) such as an additional LNA, a duplexer, a diplexer, one or more switches, and the like. In some implementations, the front-end circuit 125 may be omitted with the input 132 of the LNA 130 coupled to the antenna 110 without the front-end circuit 125.

The LNA 130 is configured to receive the RF signal from the front-end circuit 125 at the input 132, amplify the RF signal, and output the amplified RF signal at the output 134.

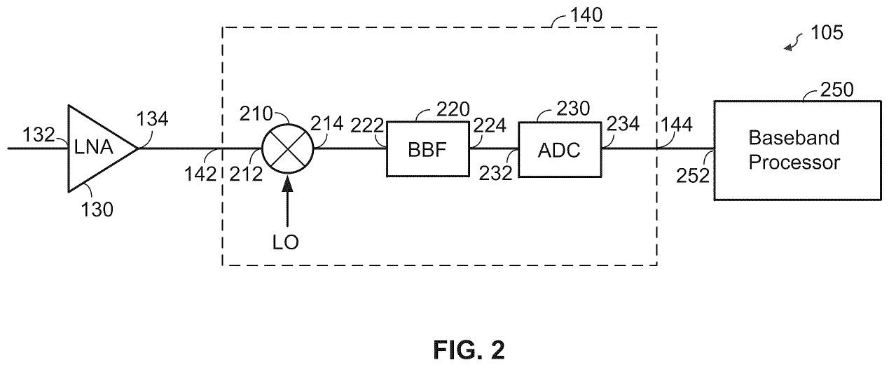

The receive circuit 140 is configured to receive the RF signal from the LNA 130 at the input 142, convert the RF signal into a baseband signal or an intermediate frequency (IF) signal, and output the baseband signal or the IF signal at the output 144. For example, the receive circuit 140 may include a mixer (shown in FIG. 2) configured to mix the RF signal with a local oscillator signal to frequency downconvert the RF signal to obtain the baseband signal or the IF signal. The receive circuit 140 may also include one or more amplifiers, one or more filters (e.g., a baseband filter), or any combination thereof. The receive circuit 140 and the LNA 130 may be integrated on the same chip (i.e., die) or separate chips.

For the example where the receive circuit 140 outputs a baseband signal, the output 144 may be coupled to a baseband processor (shown in FIG. 2). In this example, the baseband processor may decode and/or demodulate the baseband signal to recover data and/or control information from the baseband signal.

For the example where the receive circuit 140 outputs an IF signal, the output 144 may be coupled to an IF circuit (not shown). In this example, the IF circuit may frequency downconvert the IF signal to obtain a baseband signal and output the baseband signal to a baseband processor.

FIG. 1B shows an example in which the LNA 130 and the receive circuit 140 are integrated on a chip 170. The chip 170 includes a pad 160 coupled to the input 132 of the LNA 130. In this example, the front-end circuit 125 is coupled between the antenna 110 and the pad 160. Thus, in this example, the input 132 of the LNA 130 is coupled to the front-end circuit 125 through the pad 160. For implementations where the front-end circuit 125 is omitted, the pad 160 may be coupled to the antenna 110 without the front-end circuit 125.

It is to be appreciated that, in other implementations, the LNA 130 and the receive circuit 140 may be integrated on separate chips. In these implementations, the chip that includes the LNA 130 may include the pad 160 coupled to the input 132 of the LNA 130.

FIG. 2 shows an exemplary implementation of the receive circuit 140 according to certain aspects. In this example, the receive circuit 140 includes a mixer 210, a baseband filter 220, and an analog-to-digital converter (ADC) 230.

In the example in FIG. 2, the mixer 210 has an input 212 coupled to the output 134 of the LNA 130, and an output 214. The baseband filter 220 has an input 222 coupled to the output 214 of the mixer 210, and an output 224. The ADC 230 has an input 232 coupled to the output 224 of the baseband filter 220, and an output 234. The output 234 of the ADC 230 may be coupled to an input 252 of a baseband processor 250, as shown in the example in FIG. 2.

The mixer 210 is configured to receive the amplified RF signal from the LNA 130 at the input 212, mix the RF signal with a local oscillator signal (labeled “LO”) to frequency downconvert the RF signal into a baseband signal, and output the baseband signal at the output 214. The baseband filter 220 may be configured to the pass the baseband signal to the input 232 of the ADC 230 while filtering out out-of-band signals. The ADC 230 is configured to receive the baseband signal at the input 232, convert the baseband signal into a digital signal, and output the digital signal at the output 234. For example, the ADC 230 may output the digital signal to the input 252 of the baseband processor 250 for baseband processing in the digital domain.

It is to be appreciated that the receive circuit 140 may include one or more additional circuits (not shown) in the receive path between the input 142 and the output 144 of the receive circuit 140.

An LNA may include inductors (e.g., to achieve high gain in a desired frequency band and/or impedance matching). However, inductors increase die area, are not easily portable to different technologies, and may result in unwanted magnetic coupling. As a result, next generation LNAs are moving towards inductor-less LNA designs.

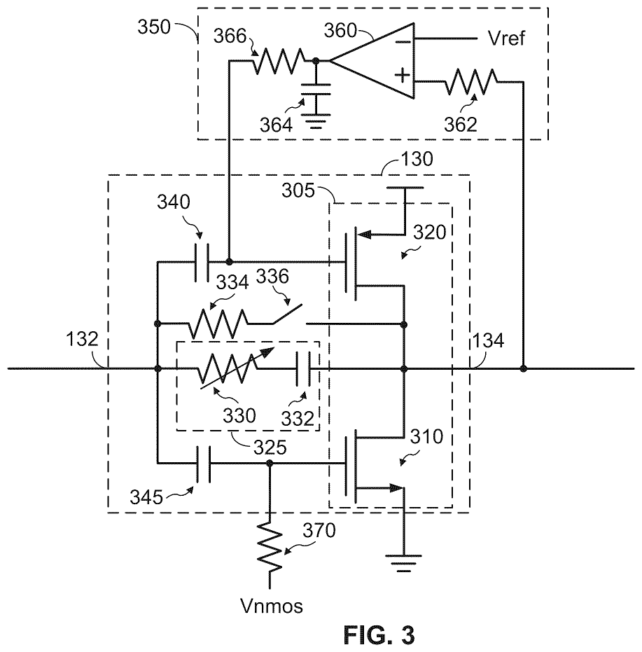

In this regard, FIG. 3 shows an example in which the LNA 130 is implemented with an inductor-less LNA according to certain aspects. However, it is to be appreciated that an inductor-less LNA is not limited to the exemplary implementation shown in FIG. 3.

In this example, the LNA 130 includes an inverter 305 coupled between the output 134 and the input 132 of the LNA 130 to provide amplification. The inverter 305 may be AC coupled to the input 132, as discussed further below.

In the example shown in FIG. 3, the inverter 305 includes a p-type metal-oxide-semiconductor (PMOS) transistor 320 and an n-type metal-oxide-semiconductor (NMOS) transistor 310. A PMOS transistor may also be referred to as a p-type field effect transistor (PFET) and an NMOS transistor may also be referred to as an n-type field effect transistor (NFET). In this example, the source of the PMOS transistor 320 is coupled to a supply rail, the source of the NMOS transistor 310 is coupled to ground (or some reference potential), and the drains of the PMOS transistor 320 and the NMOS transistor 310 are coupled to the output 134 of the LNA 130.

In the example in FIG. 3, the gate of the PMOS transistor 320 is biased using a bias circuit 350, and the gate of the NMOS transistor 310 is biased with a bias voltage Vnmos through a bias resistor 370. The bias circuit 350 is coupled between the output 134 of the LNA 130 and the gate of the PMOS transistor 320 to form a DC feedback bias loop that sets the bias voltage at the gate of the PMOS transistor 320 to achieve a desired DC bias point at the output 134. The DC feedback bias loop is very slow compared with the RF signal being amplified by the LNA 130, and may set the low frequency gain of the LNA 130.

In the example in FIG. 3, the bias circuit 350 includes an amplifier 360, a first resistor 362, a second resistor 366, and a capacitor 364. The amplifier 360 has a first input (e.g., minus input) configured to receive a reference voltage Vref, a second input (e.g., plus input), and an output. The first resistor 362 is coupled between output 134 of the LNA 130 and the second input of the amplifier 360. The second resistor 366 is coupled between the output of the amplifier 360 and the gate of the PMOS transistor 320, and the capacitor 364 is coupled between the output of the amplifier 360 and ground (or some reference potential).

In operation, the amplifier 360 senses the DC voltage at the output 134 of the LNA 130 through the first resistor 362, and adjusts the bias voltage at the gate of the PMOS transistor 320 in a direction that reduces the difference (i.e., error) between the DC voltage and the reference voltage Vref. As a result, the DC feedback bias loop forces the DC voltage at the output 134 to be approximately equal to the reference voltage Vref. Thus, a desired DC bias point may be achieved at the output 134 by setting the reference voltage Vref accordingly.

It is to be appreciated that the present disclosure is not limited to the exemplary bias circuit 350 shown in FIG. 3, and that the gate of the PMOS transistor 320 may be biased using other techniques.

In this example, the LNA 130 also includes a first AC coupling capacitor 340 coupled between input 132 and the gate of the PMOS transistor 320, and a second AC coupling capacitor 345 coupled between the input 132 and the gate of the NMOS transistor 310. The AC coupling capacitors 340 and 345 couple the RF signal at the input 132 to the gates of the PMOS transistor 320 and NMOS transistor 310 while blocking the bias voltages from the input 132.

The LNA 130 also includes a feedback loop 325 coupled between the output 134 and the input 132 of the LNA 130. In this example, the feedback loop 325 includes a feedback resistor 330 and a capacitor 332 coupled in series between the output 134 and the input 132 of the LNA 130. The capacitor 332 passes the RF signal while blocking DC signals. In this example, the feedback resistor 330 helps set the RF performance of the LNA 130 (e.g., RF gain of the LNA 130 and/or RF impedance matching).

In certain aspects, the feedback resistor 330 may be implemented with a variable resistor to provide tunability of the RF gain of the LNA 130. In these aspects, the RF gain of the LNA 130 may be tuned by tuning (e.g., programming) the resistance of the feedback resistor 330. For example, the RF gain may be increased by increasing the resistance of the feedback resistor 330, and the RF gain may be decreased by decreasing the resistance of the feedback resistor 330.

In the example in shown FIG. 3, the LNA 130 also includes a resistor 334 and a switch 336 coupled in series between the output 134 and the input 132 of the LNA 130. In this example, the resistor 334 and the switch 336 may be used to selectively lower the low frequency gain of the LNA 130, in which the low frequency gain is lower when the switch 336 is closed (i.e., turned on) compared to the low frequency gain when the switch 336 is open (i.e., turned off). It is to be appreciated that the resistor 334 and the switch 336 may be omitted in some implementations.

The LNA 130 may require that the capacitor 332 in the feedback loop 325 be large for RF impedance matching. However, making the capacitor 332 large results in a higher feedback factor, which may lead to low frequency instability (i.e., oscillation in a low frequency range). The low frequency range may be between 10 MHz to 100 MHz while the frequency of the RF signal may be within a frequency range of one to several GHz. However, it is to be appreciated that the RF signal is not limited to this exemplary frequency range.

Low frequency stability may be improved by reducing both the low frequency gain and the RF gain of the LNA 130 (e.g., by reducing the current of the LNA 130). However, the reduction in the RF gain reduces the sensitivity of the LNA 130. For implementations where the LNA 130 includes the resistor 334 and the switch 336, the low frequency gain may be reduced by closing the switch 336. However, the reduction in the low frequency gain may not be enough to prevent low frequency instability. In addition, the resistor 334 may also lower the RF gain when the switch 336 is closed.

The low frequency stability may also be improved by coupling a shunt inductor to the input 132 of the LNA 130. The shunt inductor achieves low frequency stability by reducing the low frequency gain of the LNA 130. However, the shunt inductor increases die area and is prone to isolation concerns due to unwanted magnetic coupling. In addition, the shunt inductor may also lower the RF gain unless the shunt inductor is made very large, which may not be practical in many cases.

To overcome low frequency instability, aspects of the present disclosure provide an impedance circuit coupled to the output 134 of the LNA 130, in which the impedance circuit has a low impedance in the low frequency range (i.e., frequency range in which loop stability is an issue) and a high impedance in the frequency range of the RF signal. The low impedance in the low frequency range prevents low frequency instability while the high impedance in the frequency range of the RF signal helps ensure that the RF gain of the LNA 130 is not affected. In certain aspects, the impedance circuit includes a resistor-capacitor (RC) filter that sets the frequency at which the impedance circuit transitions from the low impedance to the high impedance. The above features and other features of the present disclosure are discussed further below.

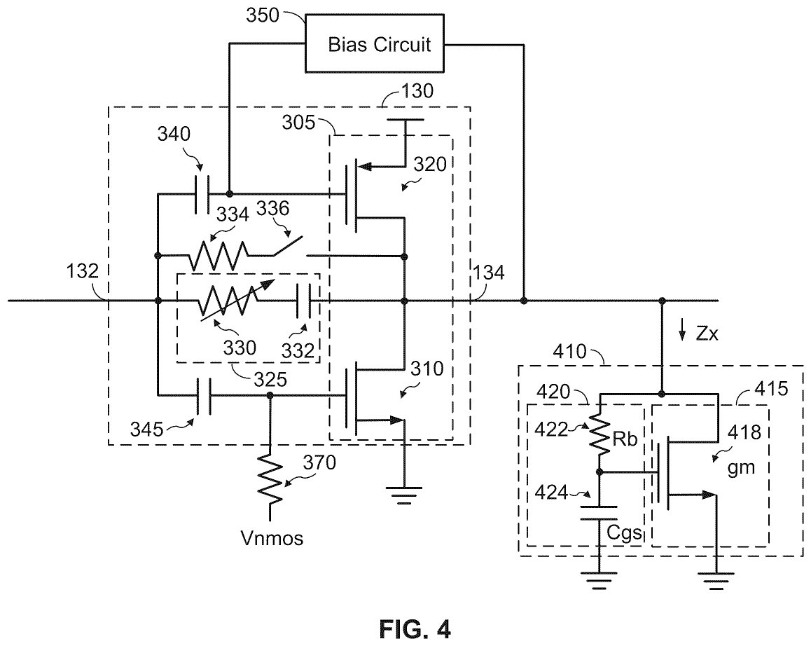

FIG. 4 shows an example of an impedance circuit 410 coupled to the output 134 of the LNA 130 according to certain aspects. The impedance circuit 410 has a frequency-dependent impedance Zx in which the impedance is low in the low frequency range and high in the frequency range of the RF signal, as discussed further below.

The impedance circuit 410 includes a transistor 415 and an RC filter 420. In this example, the drain of the transistor 415 is coupled to the output 134 of the LNA 130 and the source of the transistor 415 is coupled to ground (or some reference potential). It is to be appreciated that the transistor 415 may be physically implemented on a die with two or more individual transistors coupled in parallel and/or series. In the example in FIG. 4, the transistor 415 includes an NMOS transistor 418. However, it is to be appreciated that the transistor 415 is not limited to this example.

In the example in FIG. 4, the RC filter 420 includes a resistor 422 and a capacitor 424. The resistor 422 is coupled between the drain of the transistor 415 and the gate of the transistor 415, and the capacitor 424 is coupled between the gate of the transistor 415 and ground (or some reference potential). The resistor 422 has a resistor of R_{b}, the capacitor 424 has a capacitance of C_{gs}, and the transistor 415 has a transconductance of gm.

In this example, the impedance Zx of the impedance circuit 410 is low at approximately 1/gm in the low frequency range. This is because, in the low frequency range, the capacitor 424 acts as an open circuit, and the resistor 422 couples the drain and the gate of transistor 415, which causes the transistor 415 to behave as a diode-connect transistor with an impedance of approximately 1/gm. In the frequency range of the RF signal, the capacitor 424 acts as a short, which shunts the gate of the transistor 415 and the resistor to AC ground. As a result, the impedance of the impedance circuit 410 is approximately equal to the resistance R_{b} of the resistor 422. The resistance R_{b} may be made much higher than 1/gm to provide a high impedance in the frequency range of the RF signal.

Thus, in this example, the impedance Zx of the impedance circuit 410 is low (e.g., 1/gm) in the low frequence range and high (e.g., R_{b}) in the frequency range of the RF signal. The low impedance in the low frequency range reduces the gain of the LNA 130 in the low frequency range, which reduces the low frequency gain and improves the low frequency stability of the LNA 130. The high impedance in the frequency range of the RF signal helps ensure that the impedance circuit 410 has little to no effect on the RF gain of the LNA 130.

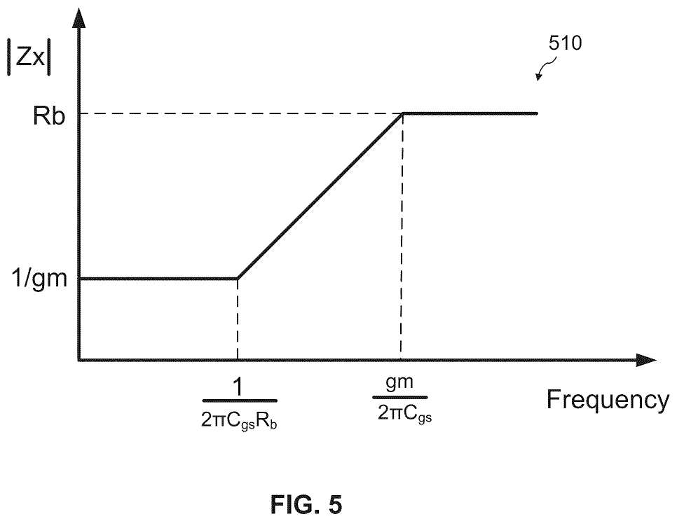

FIG. 5 shows an exemplary plot 510 of the impedance Zx of the impedance circuit 410 versus frequency. In this example, the impedance Zx is approximately 1/gm in the low frequency range and approximately Rb in the frequency range of the RF signal. As shown in the example in FIG. 5, the transition of the impedance Zx from the low impedance to the high impedance may be set by the resistance Rb of the resistor 422, the capacitance Cgs of the capacitor 424, and the transconductance gm of the transistor 415.

More particularly, in this example, the impedance Zx is approximately equal to 1/gm for frequencies below a frequency of ½πC_{gs}R_{b}. In this example, the frequency ½πC_{gs}R_{b} may be set to a frequency that is above the low frequency range (i.e., frequency range in which loop stability is an issue) and below the frequency range of the RF signal. Also, in the example in FIG. 5, the impedance Zx is approximately equal to Rb for frequencies above a frequency of gm/2πC_{gs}. In this example, the frequency gm/2πC_{gs} may be set to a frequency below the frequency range of the RF signal to help ensure that the impedance Zx is high for the RF signal.

Thus, the resistance Rb of the resistor 422, the capacitance Cgs of the capacitor 424, and/or the transconductance gm of the transistor 415 may be chosen such that the transition from the low impedance (e.g., 1/gm) to the high impedance (e.g., Rb) is between the low frequency range (i.e., frequency range in which loop stability is an issue) and the frequency range of the RF signal. This helps ensure that the impedance Zx is low in the low frequency range for improved low frequency stability, and the impedance Zx is high in the frequency range of the RF signal for high RF gain.

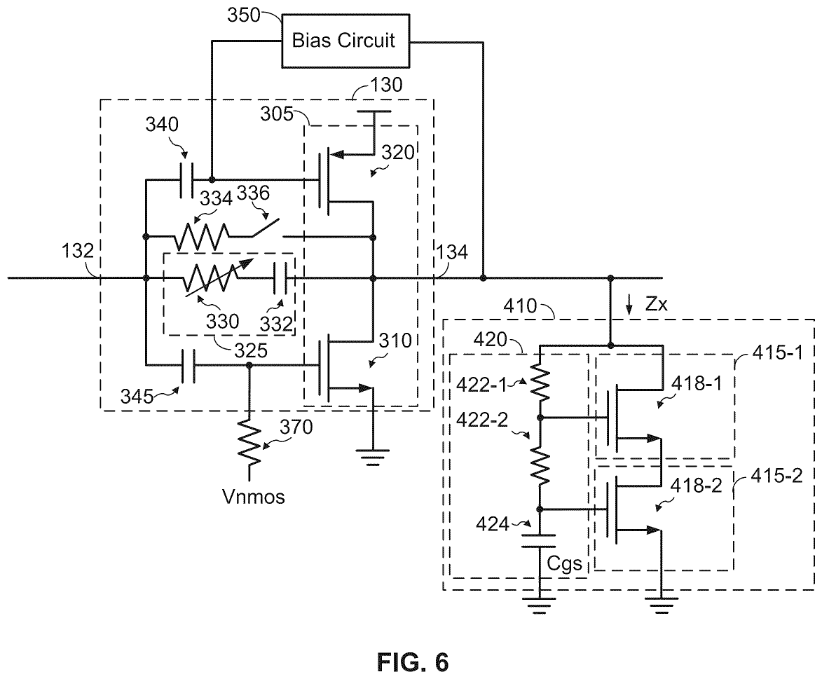

FIG. 6 shows an example in which the transistor 415 is implemented with stacked transistors including a first transistor 415-1 and a second transistor 415-2 coupled in series between the output 134 of the LNA 130 and ground (or some reference potential). In this example, the drain of the first transistor 415-1 is coupled to the output 134, the drain of the second transistor 415-2 is coupled to the source of the first transistor 415-1, and the source of the second transistor 415-1 is coupled to ground (or some reference potential). The stacked transistors 415-1 and 415-2 help reduce the leakage current of the impedance circuit 410 (which reduces DC power consumption) by dividing the DC voltage at the output 134 of the LNA 130 between the first transistor 415-1 and the second transistor 415-2.

In the example shown in FIG. 6, the first transistor 415-1 includes a first NMOS transistor 418-1 and the second transistor 415-2 includes a second NMOS transistor 418-2. However, it is to be appreciated that the present disclosure is not limited to this example.

In the example in FIG. 6, the resistor 422 of the RC filter 420 includes a first resistor 422-1 and a second resistor 422-2 coupled in series between the output 134 of the LNA 130 and the capacitor 424. In this example, the first resistor 422-1 is coupled between the drain of the first transistor 415-1 and the gate of the first transistor 415-1, and the second resistor 422-2 is coupled between the gate of the first transistor 415-1 and the gate of the second transistor 415-2. In this example, the resistance Rb is approximately equal to the sum of the resistances of the resistors 422-1 and 422-2. The capacitor 424 is coupled between the gate of the second transistor 415-2 and ground (or some reference potential).

It is to be appreciated that the impedance circuit 410 is not limited to the exemplary implementation of the LNA 130 shown in FIG. 3. The impedance circuit 410 may be used with other implementations of the LNA 130 to improve low frequency stability while having little to no impact on the RF gain by providing the low impedance (e.g., 1/gm) in the low frequency range (i.e., frequency range in which loop stability is an issue) and the high impedance (e.g., Rb) in the frequency range of the RF signal.

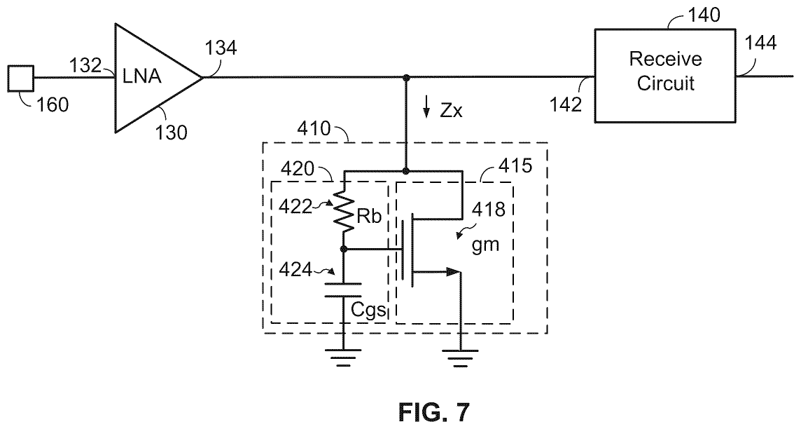

FIG. 7 shows an example where the impedance circuit 410 is coupled between the output 134 of the LNA 130 and the input 142 of the receive circuit 140. In this example, the input 132 of the LNA 130 may be coupled to the pad 160, which may be coupled to the front-end circuit 125 (shown in FIGS. 1A and 1B) or coupled to the antenna 110 without the front-end circuit 125. Thus, in this example, the input 132 of the LNA 130 may be coupled to the front-end circuit 125 or the antenna 110 through the pad 160. The receive circuit 140 may include the mixer 210, the baseband filter 220, the ADC 230, and/or one or more other circuits.

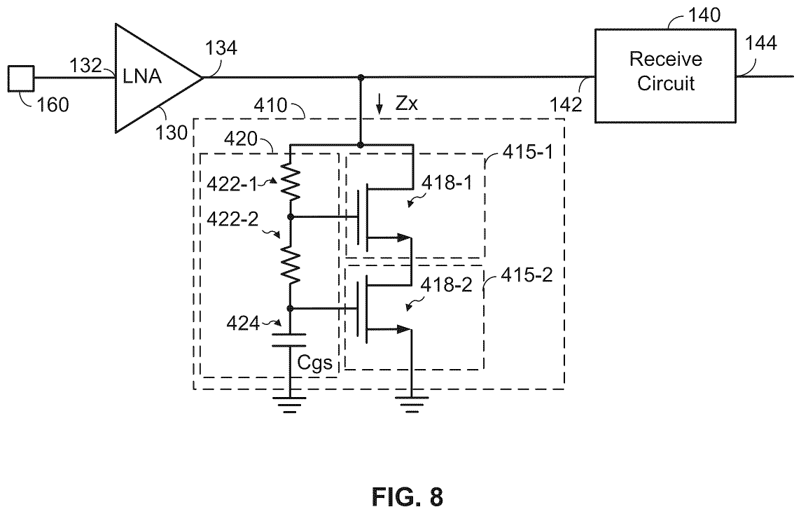

FIG. 8 shows another example of the impedance circuit 410 coupled between the output 134 of the LNA 130 and the input 142 of the receive circuit 140 in which the impedance circuit 410 includes the first transistor 415-1 and the second transistor 415-2.

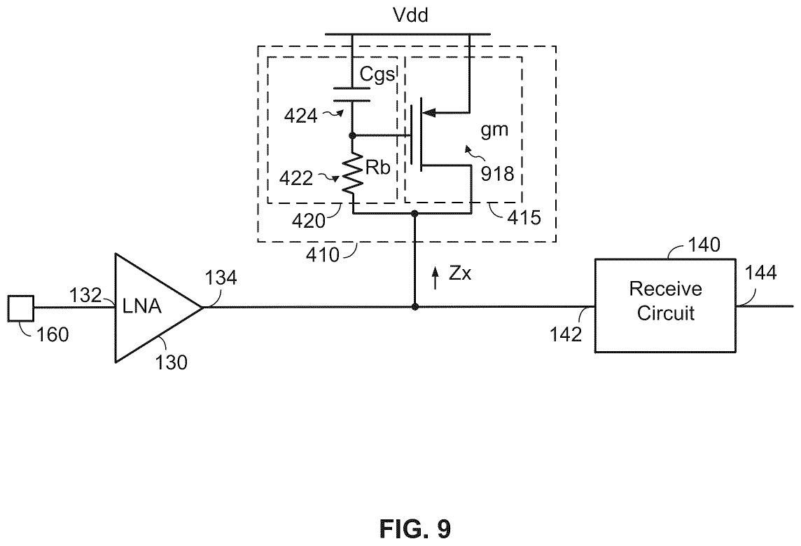

In the examples in FIGS. 4 and 7, the transistor 415 includes the NMOS transistor 418. However, it is to be appreciated that the transistor 415 is not limited to the NMOS transistor 418. In this regard, FIG. 9 shows an example in which the transistor 415 include a PMOS transistor 918. In this example, the drain of the transistor 415 is coupled to the output 134 of the LNA 130 and the source of the transistor 415 is coupled to a reference potential (e.g., a supply voltage Vdd on a supply rail). Also, in this example, the resistor 422 is coupled between the drain of the transistor 415 and the gate of the transistor 415, and the capacitor 424 is coupled between the gate of the transistor 415 and the reference potential (e.g., the supply voltage Vdd).

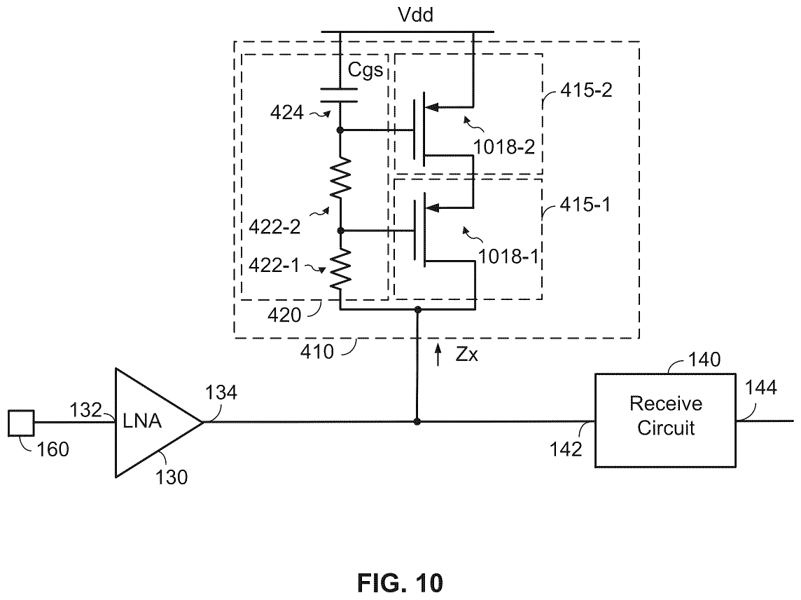

In the examples in FIGS. 6 and 8, the first transistor 415-1 includes the first NMOS transistor 418-1 and the second transistor 415-2 includes the second NMOS transistor 418-2. However, it is to be appreciated that the first transistor 415-1 is not limited to the first NMOS transistor 418-1, and the second transistor 415-2 is not limited to the second NMOS transistor 418-2. In this regard, FIG. 10 shows an example in which the first transistor 415-1 includes a first PMOS transistor 1018-1 and the second transistor 415-2 includes a second PMOS transistor 1018-2.

In this example, the drain of the first transistor 415-1 is coupled to the output 134 of the LNA 130, the drain of the second transistor 415-2 is coupled to the source of the first transistor 415-1, and the source of the second transistor 415-1 is coupled to a reference potential (e.g., the supply voltage Vdd on the supply rail). Also, in this example, the first resistor 422-1 and the second resistor 422-2 are coupled in series between the output 134 of the LNA 130 and the capacitor 424, in which the first resistor 422-1 is coupled between the drain of the first transistor 415-1 and the gate of the first transistor 415-1, and the second resistor 422-2 is coupled between the gate of the first transistor 415-1 and the gate of the second transistor 415-2. The capacitor 424 is coupled between the gate of the second transistor 415-2 and the reference potential (e.g., the supply voltage Vdd).

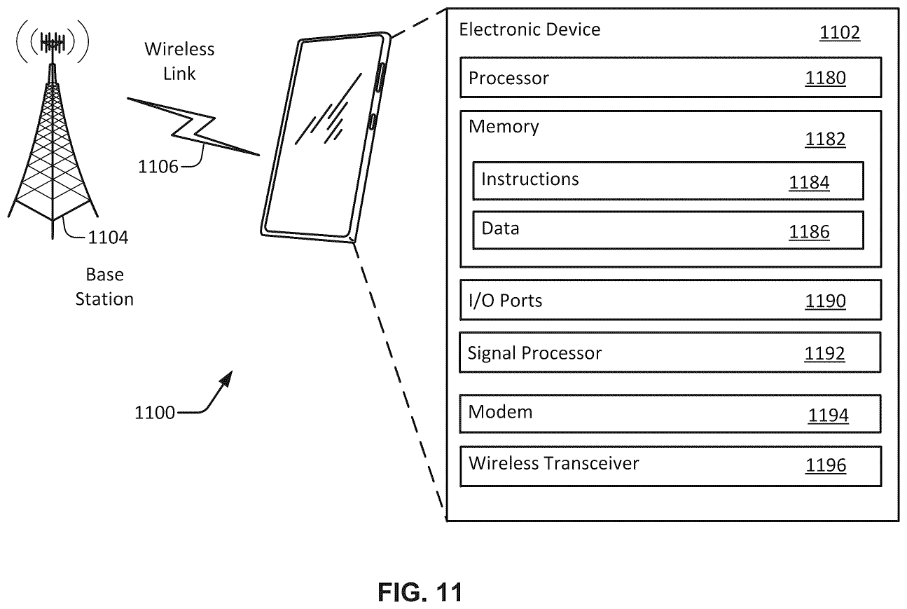

FIG. 11 is a diagram of an environment 1100 that includes a wireless device 1102 and a base station 1104. In the environment 1100, the wireless device 1102 communicates with the base station 1104 via a wireless link 1106. As shown, the wireless device 1102 is depicted as a smart phone. However, it is to be understood that the wireless device 1102 may be implemented as any suitable wireless device, such as a cellular base station, a broadband router, an access point, a cellular or mobile phone, a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, and so forth.

The base station 1104 communicates with the wireless device 1102 via the wireless link 1106, which may be implemented as any suitable type of wireless link. Although depicted as a base station tower of a cellular radio network, the base station 1104 may represent or be implemented as another device, such as a satellite, a terrestrial broadcast tower, an access point, a peer-to-peer device, a mesh network node, and so forth. The wireless link 1106 may include a downlink of data and/or control information communicated from the base station 1104 to the wireless device 1102 and an uplink of other data and/or control information communicated from the wireless device 1102 to the base station 1104. The wireless link 1106 may be implemented using any suitable communication protocol or standard, such as 3rd Generation Partnership Project Long-Term Evolution (3GPP LTE, 3GPP NR 5G), IEEE 1102.77, IEEE 1102.77, Bluetooth™, and so forth.

The wireless device 1102 includes a processor 1180 and a memory 1182. The memory 1182 may be or form a portion of a computer readable storage medium. The processor 1180 may include any type of processor, such as an application processor or a multi-core processor, that is configured to execute processor-executable instructions stored in the memory 1182. The memory 1182 may include any suitable type of data storage media, such as a volatile memory (e.g., random access memory (RAM)), a non-volatile memory (e.g., Flash memory), an optical media, a magnetic media (e.g., disk or tape), or any combination thereof. In the context of this disclosure, the memory 1182 may store instructions 1184, data 1186, and other information of the wireless device 1102.

The wireless device 1102 may also include input/output (I/O) ports 1190. The I/O ports 1190 enable data exchanges or interaction with other devices, networks, or users or between components of the wireless device 1102.

The wireless device 1102 may further include a signal processor (SP) 1192 (e.g., such as a digital signal processor (DSP)). The signal processor 1192 may function similar to the processor 1180 and may be capable of executing instructions and/or processing information in conjunction with the memory 1182.

For communication purposes, the wireless device 1102 also includes a modem 1194 (e.g., the baseband processor 250), a wireless transceiver 1196, and one or more antennas (e.g., the antenna 110). The wireless transceiver 1196 may include the LNA 130, the impedance circuit 410, and the receive circuit 140 discussed above. The wireless transceiver 1196 provides connectivity to respective networks (e.g., the base station 1104) and other wireless devices connected therewith using RF signals. The wireless transceiver 1196 may facilitate communication over any suitable type of wireless network, such as a wireless local area network (LAN) (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

Implementation examples are described in the following numbered clauses:

1. A system for wireless communications, comprising:
a low-noise amplifier (LNA); and
an impedance circuit coupled to an output of the LNA, the impedance circuit comprising:
   a transistor, wherein a drain of the transistor is coupled to the output of the LNA, and a source of the transistor is coupled to a ground or a reference potential; and
   a resistor-capacitor (RC) filter coupled to the output of the LNA and a gate of the transistor.
      2. The system of clause 1, wherein the RC filter comprises:
a resistor coupled between the drain of the transistor and the gate of the transistor; and
a capacitor coupled between the gate of the transistor and the ground.
   3. The system of clause 2, wherein the transistor comprises an n-type metal-oxide-semiconductor (NMOS) transistor.
   4. The system of clause 1, wherein the RC filter comprises;
a resistor coupled between the drain of the transistor and the gate of the transistor; and
a capacitor coupled between the gate of the transistor and the reference potential.
   5. The system of clause 4, wherein the transistor comprises a p-type metal-oxide-semiconductor (PMOS) transistor.
   6. The system of clause 4 or 5, wherein the reference potential comprises a supply voltage on a supply rail.
   7. The system of any one of clauses 1 to 6, further comprising an antenna coupled to an input of the LNA.
   8. The system of any one of clauses 1 to 7, further comprising:
an antenna; and
a front-end circuit comprising a filter, wherein the front-end circuit is coupled to between the antenna and an input of the LNA.
   9. The system of any one of clauses 1 to 8, further comprising a receive circuit comprising a mixer, wherein the receive circuit is coupled to the output of the LNA.
   10. The system of any one of clauses 1 to 9, wherein the LNA comprises:
an inverter coupled between the output of the LNA and an input of the LNA; and
a feedback resistor and a feedback capacitor coupled in series between the output of the LNA and the input of the LNA.
   11. The system of clause 10, wherein the inverter comprises:
a p-type metal-oxide-semiconductor (PMOS) transistor, wherein a source of the PMOS transistor is coupled to a supply rail, a drain of the PMOS transistor is coupled to the output of the LNA, and a gate of the PMOS transistor is coupled to the input of the LNA; and
an n-type metal-oxide-semiconductor (NMOS) transistor, wherein a drain of the NMOS transistor is coupled to the output of the LNA, a source of the NMOS transistor is coupled to the ground, and a gate of the NMOS transistor is coupled to the input of the LNA.
   12. The system of clause 11, further comprising:
a first coupling capacitor coupled between the gate of the PMOS transistor and the input of the LNA; and
a second coupling capacitor coupled between the gate of the NMOS transistor and the input of the LNA.
   13. The system of clause 11 or 12, further comprising a feedback circuit coupled between the output of the LNA and the gate of the PMOS transistor.
   14. The system of clause 13, wherein the feedback circuit comprises an amplifier having a first input configured to receive a reference voltage, a second input coupled to the output of the LNA, and an output coupled to the gate of the PMOS transistor.
   15. A system for wireless communications, comprising:
a low-noise amplifier (LNA); and
an impedance circuit coupled to an output of the LNA, the impedance circuit comprising:
   a first transistor, wherein a drain of the first transistor is coupled to the output of the LNA;
   a second transistor, wherein a drain of the second transistor is coupled to a source of the first transistor, and a source of the second transistor is coupled to a ground or a reference potential; and
   a resistor-capacitor (RC) filter coupled to the output of the LNA, a gate of the first transistor, and a gate of the second transistor.
      16. The system of clause 15, wherein the RC filter comprises:
a first resistor coupled between the drain of the first transistor and the gate of the first transistor;
a second resistor coupled between the gate of the first transistor and the gate of the second transistor; and
a capacitor coupled between the gate of the second transistor and the ground.
   17. The system of clause 16, wherein the first transistor comprises a first n-type metal-oxide-semiconductor (NMOS) transistor, and the second transistor comprises a second NMOS transistor.
   18. The system of clause 15, wherein the RC filter comprises:
a first resistor coupled between the drain of the first transistor and the gate of the first transistor;
a second resistor coupled between the gate of the first transistor and the gate of the second transistor; and
a capacitor coupled between the gate of the second transistor and the reference potential.
   19. The system of clause 18, wherein the first transistor comprises a first p-type metal-oxide-semiconductor (PMOS) transistor, and the second transistor comprises a second PMOS transistor.
   20. The system of clause 18 or 19, wherein the reference potential comprises a supply voltage on a supply rail.
   21. The system of any one of clauses 15 to 20, further comprising an antenna coupled to an input of the LNA.
   22. The system of any one of clauses 15 to 21, further comprising:
an antenna; and
a front-end circuit comprising a filter, wherein the front-end circuit is coupled to between the antenna and an input of the LNA.
   23. The system of any one of clauses 15 to 22, further comprising a receive circuit comprising a mixer, wherein the receive circuit is coupled to the output of the LNA.
   24. The system of any one of clauses 15 to 23, wherein the LNA comprises:
an inverter coupled between the output of the LNA and an input of the LNA; and
a feedback resistor and a feedback capacitor coupled in series between the output of the LNA and the input of the LNA.
   25. The system of clause 24, wherein the inverter comprises:
a p-type metal-oxide-semiconductor (PMOS) transistor, wherein a source of the PMOS transistor is coupled to a supply rail, a drain of the PMOS transistor is coupled to the output of the LNA, and a gate of the PMOS transistor is coupled to the input of the LNA; and
an n-type metal-oxide-semiconductor (NMOS) transistor, wherein a drain of the NMOS transistor is coupled to the output of the LNA, a source of the NMOS transistor is coupled to the ground, and a gate of the NMOS transistor is coupled to the input of the LNA.
   26. The system of clause 25, further comprising:
a first coupling capacitor coupled between the gate of the PMOS transistor and the input of the LNA; and
a second coupling capacitor coupled between the gate of the NMOS transistor and the input of the LNA.
   27. The system of clause 25 or 26, further comprising a feedback circuit coupled between the output of the LNA and the gate of the PMOS transistor.
   28. The system of clause 27, wherein the feedback circuit comprises an amplifier having a first input configured to receive a reference voltage, a second input coupled to the output of the LNA, and an output coupled to the gate of the PMOS transistor.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a direct current (DC) ground or an alternating current (AC) ground, and thus the term “ground” covers both possibilities. An AC ground may be provided by a DC voltage.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A system for wireless communications, comprising:
a low-noise amplifier (LNA); and
an impedance circuit coupled to an output of the LNA, the impedance circuit comprising:
a transistor, wherein a drain of the transistor is coupled to the output of the LNA, and a source of the transistor is coupled to a ground or a reference potential; and
a resistor-capacitor (RC) filter coupled to the output of the LNA and a gate of the transistor.

2. The system of claim 1, wherein the RC filter comprises:
a resistor coupled between the drain of the transistor and the gate of the transistor; and
a capacitor coupled between the gate of the transistor and the ground.

3. The system of claim 2, wherein the transistor comprises an n-type metal-oxide-semiconductor (NMOS) transistor.

4. The system of claim 1, wherein the RC filter comprises:
a resistor coupled between the drain of the transistor and the gate of the transistor; and
a capacitor coupled between the gate of the transistor and the reference potential.

5. The system of claim 4, wherein the transistor comprises a p-type metal-oxide-semiconductor (PMOS) transistor.

6. The system of claim 1, wherein the LNA comprises:
an inverter coupled between the output of the LNA and an input of the LNA; and
a feedback resistor and a feedback capacitor coupled in series between the output of the LNA and the input of the LNA.

7. The system of claim 6, wherein the inverter comprises:
a p-type metal-oxide-semiconductor (PMOS) transistor, wherein a source of the PMOS transistor is coupled to a supply rail, a drain of the PMOS transistor is coupled to the output of the LNA, and a gate of the PMOS transistor is coupled to the input of the LNA; and
an n-type metal-oxide-semiconductor (NMOS) transistor, wherein a drain of the NMOS transistor is coupled to the output of the LNA, a source of the NMOS transistor is coupled to the ground, and a gate of the NMOS transistor is coupled to the input of the LNA.

8. The system of claim 7, further comprising:
a first coupling capacitor coupled between the gate of the PMOS transistor and the input of the LNA; and
a second coupling capacitor coupled between the gate of the NMOS transistor and the input of the LNA.

9. The system of claim 7, further comprising a feedback circuit coupled between the output of the LNA and the gate of the PMOS transistor.

10. The system of claim 9, wherein the feedback circuit comprises an amplifier having a first input configured to receive a reference voltage, a second input coupled to the output of the LNA, and an output coupled to the gate of the PMOS transistor.

11. A system for wireless communications, comprising:
a low-noise amplifier (LNA); and
an impedance circuit coupled to an output of the LNA, the impedance circuit comprising:
a first transistor, wherein a drain of the first transistor is coupled to the output of the LNA;
a second transistor, wherein a drain of the second transistor is coupled to a source of the first transistor, and a source of the second transistor is coupled to a ground or a reference potential; and
a resistor-capacitor (RC) filter coupled to the output of the LNA, a gate of the first transistor, and a gate of the second transistor.

12. The system of claim 11, wherein the RC filter comprises:
a first resistor coupled between the drain of the first transistor and the gate of the first transistor;
a second resistor coupled between the gate of the first transistor and the gate of the second transistor; and
a capacitor coupled between the gate of the second transistor and the ground.

13. The system of claim 12, wherein the first transistor comprises a first n-type metal-oxide-semiconductor (NMOS) transistor, and the second transistor comprises a second NMOS transistor.

14. The system of claim 11, wherein the RC filter comprises:
a first resistor coupled between the drain of the first transistor and the gate of the first transistor;
a second resistor coupled between the gate of the first transistor and the gate of the second transistor; and
a capacitor coupled between the gate of the second transistor and the reference potential.

15. The system of claim 14, wherein the first transistor comprises a first p-type metal-oxide-semiconductor (PMOS) transistor, and the second transistor comprises a second PMOS transistor.

16. The system of claim 11, wherein the LNA comprises:
an inverter coupled between the output of the LNA and an input of the LNA; and
a feedback resistor and a feedback capacitor coupled in series between the output of the LNA and the input of the LNA.

17. The system of claim 16, wherein the inverter comprises:
a p-type metal-oxide-semiconductor (PMOS) transistor, wherein a source of the PMOS transistor is coupled to a supply rail, a drain of the PMOS transistor is coupled to the output of the LNA, and a gate of the PMOS transistor is coupled to the input of the LNA; and
an n-type metal-oxide-semiconductor (NMOS) transistor, wherein a drain of the NMOS transistor is coupled to the output of the LNA, a source of the NMOS transistor is coupled to the ground, and a gate of the NMOS transistor is coupled to the input of the LNA.

18. The system of claim 17, further comprising:
a first coupling capacitor coupled between the gate of the PMOS transistor and the input of the LNA; and
a second coupling capacitor coupled between the gate of the NMOS transistor and the input of the LNA.

19. The system of claim 17, further comprising a feedback circuit coupled between the output of the LNA and the gate of the PMOS transistor.

20. The system of claim 19, wherein the feedback circuit comprises an amplifier having a first input configured to receive a reference voltage, a second input coupled to the output of the LNA, and an output coupled to the gate of the PMOS transistor.
